(19) United States
(12) Patent Application Publication
(10) Pub. No.: US 2010/0111649 A1
(43) Pub. Date: May 6, 2010

(54) TRANSFER DEVICE AND VACUUM PROCESSING APPARATUS USING THE SAME

(75) Inventors: Hirofumi MINAMI, Chigasaki-shi (JP); Kazuhiro Fujimura, Chigasaki-shi (JP)

Correspondence Address: KRATZ, QUINTOS & HANSON, LLP, 1420 K Street, N.W., Suite 400, WASHINGTON, DC, 20005, US

(73) Assignee: ULVAC, INC., Chigasaki-shi (JP)

(21) Appl. No.: 12/617,270

(22) Filed: Nov. 12, 2009

Related U.S. Application Data
(63) Continuation of application No. PCT/JP2008/058811, filed on May 14, 2008.

(30) Foreign Application Priority Data
May 15, 2007 (JP) 2007-128904

(51) Int. Cl. H01L 21/677

(52) U.S. Cl. 414/217

(57) ABSTRACT

A transfer device that avoids the problem of a vacuum apparatus being contaminated by grease, dust, and others and having a small base area is provided. Corrosion protection according to an existing technology may be applied to the transfer device. The transfer device may have a transfer section to support and transfer an object to be transferred, a link to transmit power from a device main body to the transfer section and move the transfer section in the horizontal direction, and a guide mechanism disposed between the device main body and the transfer section guide. The guide mechanism may have pivotally connected first and second guide arms. The first guide arm at one end of the guide mechanism may be attached to the device main body, and the second guide arm at the other end thereof may be attached to the transfer section.

This application is a continuation of International Application No. PCT/JP2008/058811, filed May 14, 2008, which claims priority to Japan Patent Application No. 2007-128904, filed on May 15, 2007. The entire disclosures of the prior applications are herein incorporated by reference in their entireties.

### FIELD OF THE INVENTION

The present invention generally relates to a transfer device to transfer a substrate for processing, such as a semiconductor wafer. In particular, the invention relates to a transfer device suitable for a carry-in and carry-out operation of a substrate to be processed in a vacuum processing apparatus having one or more process chambers for performing various processing on the substrate to be processed.

### BACKGROUND OF THE INVENTION

As a transfer device of this kind, a device disclosed in JPA No. 2005-125479, for example, has heretofore been known.

FIGS. 8A to 8C show the basic configuration of a conventional technology.

As shown in FIGS. 8A to 8C, in a transfer device 200, a lengthy guide member 202 is fixed to a horizontally rotatable swivel 201. An end of a first arm 203 is attached to a drive motor (not shown) so as to be rotatable around a spindle 203a piercing through a base portion 202a of the guide member 202 and the swivel 201.

A linear guide 204 is provided on an extended portion 202b of the guide member 202, and a moving member 205 is disposed so as to move in the direction indicated by the arrow X or the opposite direction along the linear guide 204. A transfer table 206 for mounting an object to be transferred 300, such as a wafer or a glass substrate, is attached to a tip of the moving member 205.

In addition, an end of a second arm 207 is pivotally supported with the other end of the first arm 203. The other end thereof is pivotally supported with the moving member 205. The base portion 202a of the guide member 202 and the moving member 205 are connected to each other through the first and second arms 203 and 207.

In the case of the conventional technology having such a configuration, during the expansion and contraction movement, the first arm 203 rotates, and the second arm 207 also rotates in accordance with the rotation of the first arm 203. Thereby, the moving member 205 moves linearly along the extended portion 202b of the linear guide 204.

Meanwhile, the rotation movement is carried out by activating the drive motor (not shown) and rotating the swivel 201 in a state that the first and second arms 203 and 207 are located at the contraction position.

In the conventional technology, because the device is configured so as to sustain the weight of the object to be transferred 300, including the swivel 201, and the weight of the moving member 205 by the linear guide 204 and the guide member 202, a material having a stiffness of an extent enough to move the moving member 205 on the linear guide 204 is used for the first and second arms 203 and 207; so that the weight of the object to be transferred 300 and others cannot be sustained by the first and second arms 203 and 207.

As a result, the problem of the conventional technology is that, when the weight of the object to be transferred 300 is heavy, the linear guide section (the first and second arms 203, 207 and the moving member 205) does not move smoothly and the object to be transferred 300 cannot be transferred to a right position.

In a conventional device, it is attempted to overcome the problem by increasing the quantity of a lubricant (grease) fed to the slide portion of the linear guide section or by enlarging the size of the linear guide. However, if the quantity of a lubricant increases, in particular, in the case that the transfer device is used in a vacuum device, excessive grease may contaminate the interior of the vacuum device and the object to be transferred. Furthermore, if the size of the linear guide is increased, the whole weight of the device increases. Thus, the power of the drive motor also has to be increased to that extent, and the overall size of the whole device also increases.

Moreover, in the conventional transfer device 200 shown in FIGS. 8A to 8C, because the extended portion 202b of the guide member 202 and the linear guide 204 thereon protrude frontward from the swivel 201, even when the moving member 205 is located right above the swivel 201, for example, the rotation radius of the device cannot be shortened beyond the position of the tip of the extended portion 202b. Consequently, the base area of the device cannot be reduced.

Other conventional technologies are disclosed in, for example, Japanese Patent Publication Nos. 2001-185596, 2002-362738, 2003-209155, 2004-323165, 2004-130459, 2005-12139, and others.

In such a conventional device, the movement of the “elbow portion” of a parallel link arm is controlled by transmitting the movement of an “upper arm” of a parallel link arm mechanism to a “lower arm” using a linear guide. When a large force is imposed on a transfer arm, or when the weight of an object to be transferred increases, there is a problem that the linear guide section does not move smoothly, and that the transferring arm also does not move smoothly so that the object to be transferred cannot be transferred to the right position.

In such a conventional device, attempts have been made to overcome the above-described problems by increasing the quantity of a lubricant (grease) fed to the slide portion of the linear guide section or by enlarging the size of the linear guide. However, if the quantity of a lubricant is increased, in cases where the transfer device is used in a vacuum device, excessive grease may contaminate the interior of the vacuum device and the object to be transferred. Further, if the size of the linear guide is increased, the whole weight of the device increases, and the power of the drive motor also has to be increased to the same extent, resulting in the increase of the overall size of the entire device.

Sometimes, an apparatus based on the aforementioned conventional technology or another similar conventional technology is used in a corrosive gas ambience. In such a case, corrosion protection is applied to the surfaces of constituent members in the device in order to prevent members from corrosion. However, a technology for the corrosion protection of a linear guide is not yet well established at the present. Thus, the cost for corrosion protection increases, and the production cost of the device also increases.

### SUMMARY OF THE INVENTION

The present invention has been established in order to solve the conventional technological problems described above, and an object of the present invention is to provide a transfer device that does not cause the problem of grease or the like contaminating a vacuum apparatus.

Another object of the present invention is to provide a transfer device that does not take up a large space In particular, certain embodiments of the transfer device have a small base area or device footprint.

Yet another object of the present invention is to provide a transfer device that allows a rotary element (a bearing or the like) to undergo corrosion protection easily by an existing technology. The present invention, which is established to attain the above objectives, is generally directed to a transfer device wherein the transfer device includes a transfer section to support and transfer an object to be transferred, a power transmission mechanism to transmit power from a device main body to the transfer section and to move the transfer section toward a direction intersecting with a reference direction, and a guide mechanism disposed between the device main body and the transfer section to guide the direction of the movement of the transfer section; and the guide mechanism has a plurality of pivotally connected guide arms and is configured such that each of the guide arms rotate toward a direction containing the component of the reference direction.

An embodiment of the present invention is directed to a transfer device with the aforementioned features, wherein the guide arms of the guide mechanism are configured such that a guide arm at one end of the guide mechanism may be attached to the device main body and a guide arm at the other end thereof may be attached to the transfer section.

An embodiment of the present invention is directed to a transfer device having any combination of the aforementioned features, wherein the guide mechanism has a first guide arm and a second guide arm; an end of the first guide arm is pivotally supported with the device main body in the manner of being rotatable in the vertical direction; an end of the second guide arm is pivotally supported with the other end of the first guide arm in the manner of being rotatable in the vertical direction; and the other end of the second guide arm is pivotally supported with the transfer section in the manner of being rotatable in the vertical direction.

An embodiment of the present invention is directed to a transfer device having any combination of the aforementioned features, wherein the power transmission mechanism has a drive arm and a driven arm; an end of the drive arm is fixed to a drive shaft of the device main body in the manner of being rotatable in the horizontal direction; an end of the driven arm is pivotally supported with the other end of the drive arm in the manner of being rotatable in the horizontal direction; and the other end of the driven arm is pivotally supported with the transfer section in the manner of being rotatable in the horizontal direction.

An embodiment of the present invention is directed to a transfer device having any combination of the aforementioned features, wherein the power transmission mechanism has a drive-side parallelogram link mechanism having the drive arm and a driven-side parallelogram link mechanism formed with a predetermined link in the drive-side parallelogram link mechanism.

An embodiment of the present invention is directed to a transfer device having any combination of the aforementioned features, wherein the guide mechanism is connected to the power transmission mechanism and configured so as to constrain the relative movement of the drive-side parallelogram link mechanism and the driven-side parallelogram link mechanism.

An embodiment of the present invention is directed to a transfer device having any combination of the aforementioned features, wherein an end of the power transmission mechanism on the side of the device main body is attached to a rotating section disposed on the device main body.

An embodiment of the present invention is directed to a vacuum processing apparatus having a transfer chamber containing any one of the aforementioned transfer devices, and a vacuum processing chamber communicating with the transfer chamber and being configured so as to receive and deliver an object to be processed using the transfer device.

In the case of such an embodiment, since a guide mechanism having a plurality of pivotally connected guide arms is installed in place of a linear guide employed in a conventional technology and each of the guide arms is configured so as to rotate in a direction including the component of a reference direction (for example, the component of the vertical direction), it is possible to: avoid increasing the size of the whole device; reduce the base area of the device in particular; and apply corrosion protection easily by an existing technology. Furthermore, it is possible to avoid loading a force onto the guide mechanism in a reference direction, in particular, in the vertical direction.

Moreover, since the frictional resistance can be avoided at the slide portion of a linear guide, unlike in the conventional technology, the power transmission mechanism comprising arms and the like moves smoothly and an object to be transferred can be transferred to a right position.

Furthermore, because it is not necessary to use a large linear guide, unlike in a conventional technology, it is possible to obtain a transfer device that particularly avoids the increase in the size of the drive motor for rotation and the increase in the production cost.

Moreover, when a transfer device according to the present embodiment is used in a vacuum apparatus, there are some cases that grease (oil) cannot be used as a lubricant and a dry lubricant (a solid lubricant) is used instead. Some devices currently use a solid lubricant as the lubricant for a linear guide. However, the load capacity of such a device is small, and the service life is short.

However, a bearing technology using a solid lubricant is far more established than the linear guide technology, and the load capacity of a bearing technology tends to be large, and the service life is long.

Since a transfer device according to this embodiment is configured only by rotary elements (configured so as to be pivotally supported with bearings), when it is necessary to use a dry lubricant (a solid lubricant), it is possible to use a technologically established dry bearing so that it is possible to provide a transfer device having a large load capacity and a long service life without the contamination of an object to be transferred and the vacuum environment.

In an embodiment of the present invention, in the case that the guide arms of the guide mechanism are configured such that a guide arm at one end of the guide mechanism is attached to the device main body and a guide arm at the other end thereof is attached to the transfer section, in particular, in the case that: the guide mechanism has a first guide arm and a second guide arm; an end of the first guide arm is pivotally supported with the device main body in the manner of being rotatable in the vertical direction; an end of the second guide arm is pivotally supported with the other end of the first guide arm in the manner of being rotatable in the vertical direction; and the other end of the second guide arm is pivotally supported with the transfer section in the manner of being rotatable in the vertical direction, it is possible to reduce the force loaded on the guide mechanism in the vertical direction and simplify the configuration of the guide mechanism so that it is possible to provide a small transfer device that allows smoother transfer of an object to be transferred.

In an embodiment of the present invention, in the case that: the power transmission mechanism has a drive arm and a driven arm; an end of the drive arm is fixed to a drive shaft of the device main body in the manner of being rotatable in the horizontal direction; an end of the driven arm is pivotally supported with the other end of the drive arm in the manner of being rotatable in the horizontal direction; and the other end of the driven arm is pivotally supported with the transfer section in the manner of being rotatable in the horizontal direction, a gear is not required at the transfer section in the present invention although, for example in the case of a transfer device of a flog-leg type arm mechanism, a gear is used at the transfer section as a constraint mechanism, and it is possible for this embodiment to provide a transfer device that does not contaminate an object to be transferred (for example, a wafer or a glass substrate) with dust generated from the gear. In an embodiment of the present invention, in the case that the power transmission mechanism has a drive-side parallelogram link mechanism having the drive arm, and a driven-side parallelogram link mechanism formed with a predetermined link in the drive-side parallelogram link mechanism, it is possible to sustain the weight of an object to be transferred and the transfer section by the four arms so that it is possible to provide a compact transfer device without the increase of the thickness of the arms. In addition, because the weight of an object to be transferred and the transfer section is sustained with the four arms, it is possible to reduce the force loaded on the arm joining sections (joints) and provide a transfer device that allows smooth movement of the arm joining sections (joints).

In such a case, if the guide mechanism is connected to the power transmission mechanism and configured so as to constrain the relative movement of the drive-side parallelogram link mechanism and the driven-side parallelogram link mechanism, a linear guide and a gear for constraint are not required in the present invention although, for example, a conventional transfer device having a parallelogram link mechanism type arm (Japanese Patent 2531261 or the likes) is configured so as to constrain the relative movement of the drive-side parallelogram link mechanism and the driven-side parallelogram link mechanism with a linear guide and a gear. Consequently, it is possible to provide a transfer device that does not contaminate an object to be transferred (for example, a wafer or a glass substrate) by oil coming from the lubricant (grease) at the slide portion of a linear guide and dust generated from the gear.

In an embodiment of the present invention, in the case that the end of the power transmission mechanism on the side of the device main body is attached to a rotating section provided on the device main body, in addition to the above effects, a guide member conventionally required to support and fix a linear guide is not required in a transfer device that can change the direction of the transfer of an object to be transferred by rotation so that it is possible to downsize the drive motor for rotation and resultantly provide a transfer device with a small size and a low production cost.

In the meantime, with a vacuum processing apparatus having a transfer chamber containing a transfer device according to the present invention; and a vacuum processing chamber communicating with the transfer chamber and being configured so as to receive and deliver an object to be processed with the transfer device, it is possible to provide a vacuum processing apparatus that has a small size and is hardly contaminated by dust and oil.

The present invention makes it possible to provide a transfer device that does not contaminate a vacuum device and others by grease and dust.

Further, the present invention makes it possible to provide a transfer device that does not cause the size of the whole device to increase, can reduce the base area of the device in particular, and can apply corrosion protection easily by an existing technology. In addition, the present invention makes it possible to provide a transfer device that can be driven with a motor having a small drive force.

As a result, the present invention makes it possible to provide a vacuum processing apparatus that has a small size, and is hardly contaminated by dust and oil, and has a small base area.

### BRIEF DESCRIPTION OF THE DRAWINGS

FIGS. 1A to 1C show a general configuration in an embodiment of a transfer device according to the present invention;

FIG. 1A shows a plan view of the transfer device;

FIG. 1B shows a side view of the transfer device; and

FIG. 1C shows a view of an internal constitution of the transfer device.

FIG. 2 is an explanatory plan view showing the attachment position of a guide mechanism in the above transfer device.

FIGS. 3A to 3C are explanatory views showing movement in the present embodiment.

FIGS. 4A and 4B show a general configuration in another embodiment of a transfer device according to the present invention;

FIG. 4A shows a plan view of the transfer device; and

FIG. 4B shows a front view of the transfer device depicted in FIG. 4A.

FIG. 5 is a plan view showing the substantial part of the above transfer device.

FIG. 6 is a plan view showing a general configuration in another embodiment of a transfer device according to the present invention.

FIG. 7 is a plan view schematically showing a configuration in an embodiment of a vacuum processing apparatus having a transfer device according to the present invention.

FIGS. 8A to 8C show a general configuration of a transfer device according to a conventional technology;

FIG. 8A shows a plan view of the conventional technology;

FIG. 8B shows a front view of the conventional technology depicted in FIG. 8A; and

FIG. 8C shows a side view of the conventional technology depicted in FIG. 8A.

### DETAILED DESCRIPTION OF THE INVENTION

Preferable embodiments according to the present invention are hereunder explained in detail in reference to the drawings. It is to be understood that these embodiments are provided for illustrative purposes and that the present invention is not limited by these examples.

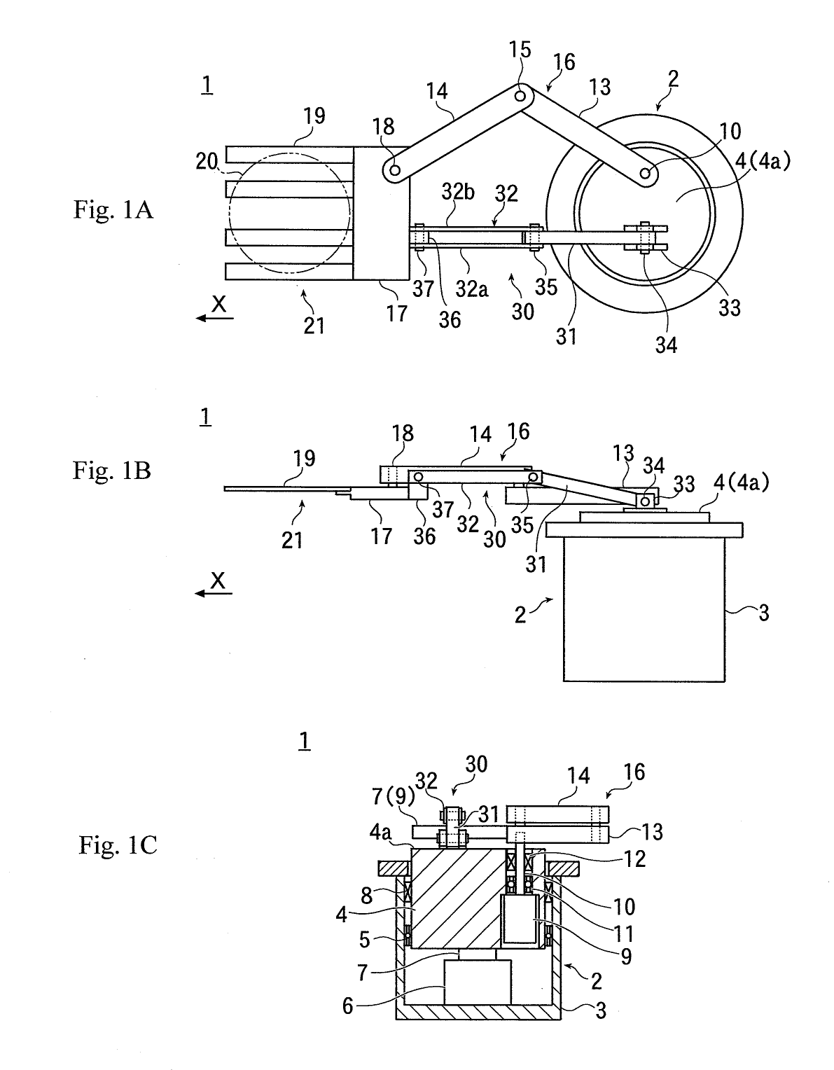

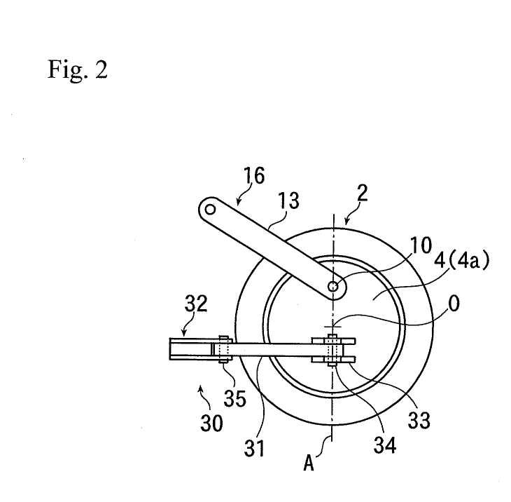

FIGS. 1A to 1C show a general configuration in an embodiment of a transfer device according to the present invention. FIG. 1A shows a plan view, FIG. 1B shows a side view, and FIG. 1C is a view showing the internal constitution of the transfer device. Furthermore, FIG. 2 is an explanatory plan view showing the attachment position of a guide mechanism in the transfer device.

As shown in FIGS. 1A to 1C, a transfer device 1 according to the present embodiment has a cylindrical casing 3 functioning as a device main body 2, and a swivel 4 is contained in the casing 3.

The swivel 4 is formed into a cylindrical shape and attached rotatably to the inner wall of the casing 3 through a bearing 5.

A drive motor 6 is disposed on the bottom face of the casing 3, and a tip of a rotary shaft 7 disposed above the drive motor 6 is fixed to the swivel 4. The device is configured such that the swivel 4 rotate (swing) (in a clockwise or counterclockwise direction) around the rotary shaft 7 extending in the vertical direction in the casing 3 by activating the drive motor 6.

The space between the swivel 4 and the inner wall of the casing 3 is partitioned with a shaft seal 8 so as to keep a vacuum state.

A drive motor 9 is disposed in the interior of the swivel 4, a rotary shaft 10 of the drive motor 9 is supported with a bearing 11, and a tip thereof protrudes from an upper face 4a of the swivel 4 in the vertical direction.

Furthermore, the space between the rotary shaft 10 of the drive motor 9 and the inner wall of the swivel 4 is partitioned with a shaft seal 12 so as to keep a vacuum state.

An end of a linear first arm (drive arm) 13 having a predetermined length is fixed to the tip of the rotary shaft 10 of the drive motor 9, and the first arm 13 rotates around the rotary shaft 10 in the horizontal direction by activating the drive motor 9.

A second arm (driven arm) 14 similar to the first arm 13 is pivotally supported with the other end of the first arm 13 in the manner of being rotatable around a spindle 15 in the horizontal direction, and the first and second arms 13 and 14 constitute an expandable and contractible link (a power transmission mechanism) 16.

A tabular moving member 17, for example, is pivotally supported with the other end of the second arm 14 in the manner of being rotatable around a spindle 18 in the horizontal direction. A transfer table 19 for loading an object to be transferred 20, such as a wafer or a glass substrate, is attached to the front side edge of the moving member 17 in the direction of arm extension (the direction indicated with the arrow X in the figures). The moving member 17 and the transfer table 19 constitute a parallel (horizontally) movable transfer section 21.

Further, the upper face 4a of the swivel 4 is connected to the moving member 17 through a guide mechanism 30.

The guide mechanism 30 has a plurality of pivotally connected linear guide arms (first and second two guide arms 31 and 32 in the case of the present embodiment).

The first guide arm 31 is pivotally supported at an end thereof with a support member 33 formed on the upper face 4a of the swivel 4, and the first guide arm 31 rotates around a spindle 34 in the vertical direction.

A pair of identical second guide arms 32 (32a and 32b) is provided so as to face each other, and one end of the first guide arm 31 is interpose therebetween. The first guide arm 31 is pivotally supported with the other end of the first guide arm 31 in the manner of being rotatable around a spindle 35 in the vertical direction.

Moreover, the other ends of the second guide arms 32a and 32b are pivotally supported in the manner of interposing a support post 36 attached to the side edge of the moving member 17 in the back direction of arm extension and being rotatable around a spindle 37 in the vertical direction.

Each of the three spindles 34, 35, and 37 is configured with a bearing and is disposed such that the center axis of rotation may be horizontal and form a right angle to the moving direction of the moving member 17 (the direction indicated by the arrow X or the opposite direction in the figures).

In the present embodiment, by this configuration, the range (direction) wherein the first and second guide arms 31 and 32 of the guide mechanism 30 can move is constrained only in the direction parallel to the X direction.

Although the present invention is not particularly limited to this embodiment, from the viewpoint of the stability of operation, the spindle 34 of the second guide arm 32 may be positioned on the straight line A passing through the rotation center axis O on the upper face 4a of the swivel 4 on the opposite side to the rotary shaft 10 of the drive motor 9 across the rotation center axis O, as shown in FIG. 2.

In this embodiment, as a material for the first arm 13 and the second arm 14, a material having a stiffness enough to sustain the weight of the transfer table 19 including the object to be transferred 20 and the weight of the moving member 17 is adopted. By this configuration, the force loaded on the guide mechanism 30 in the vertical direction can be avoided.

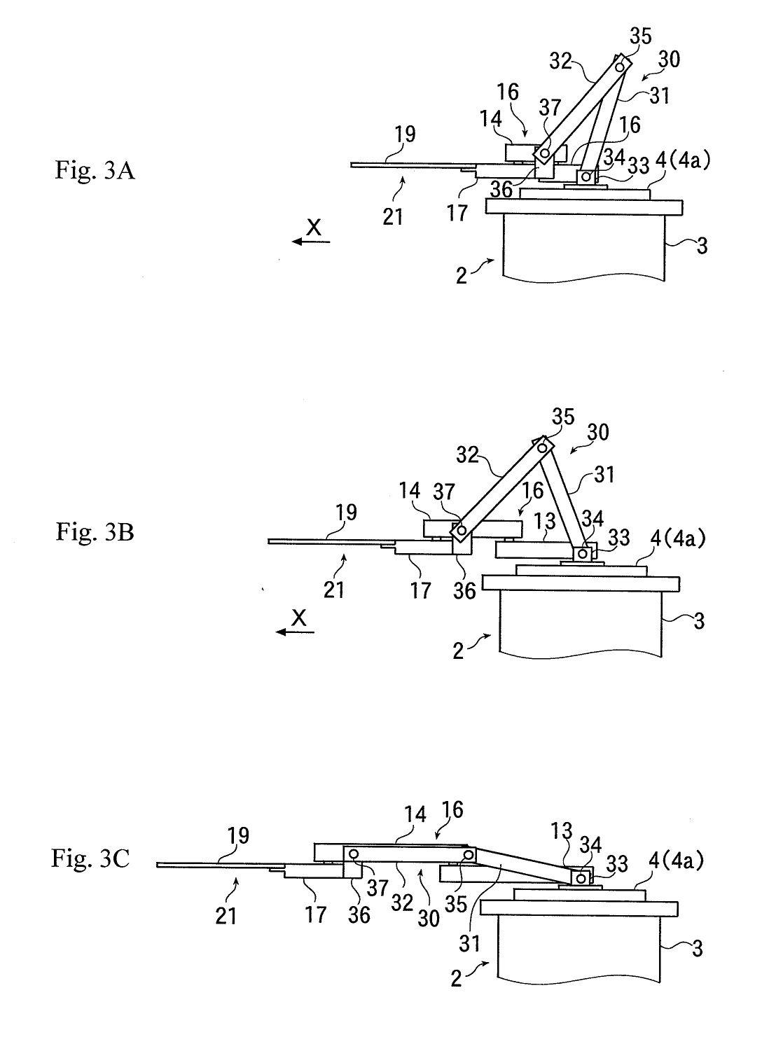

FIGS. 3A to 3C are explanatory views showing the operation of the present embodiment.

In the case of the embodiment having the configuration depicted in FIGS. 3A to 3C, in expansion and contract ion movement, when the drive motor 9 is activated, the first arm 13 rotates around the rotary shaft 10 in the horizontal direction, the second arm 14 also rotates around the spindles 15 and 18 in the horizontal direction in accordance with the movement of the first arm 13, and thereby power is transmitted to the moving member 17.

As discussed above, because the movable range of the first and second guide arms 31 and 32 of the guide mechanism 30 is constrained only in the direction parallel to the X direction, the moving member 17 moves parallel in the X direction (or in the opposite direction) as shown in FIGS. 3A to 3C.

FIG. 3A shows the contracted posture, FIG. 3B shows an intermediate posture, and FIG. 3C shows the expanded posture.

The rotation movement is carried out by activating the drive motor 9 and rotating the swivel 4 in the state that the moving member 17 is in the contracted posture (FIG. 3A).

As discussed above, because each of the first and second guide arms 31 and 32 constituting the guide mechanism 30 is pivotally supported so as to rotate in the vertical direction, it is possible to avoid increasing the size of the whole device; reduce the base area of the device in particular; and apply corrosion protection easily by an existing technology. Further, the guide mechanism 30 is designed so as to avoid force loaded in the vertical direction. In addition, because the frictional resistance can be avoided at the slide portion of a linear guide unlike a conventional technology, the link 16 consisting of the first and second arms 13 and 14 moves smoothly and an object to be transferred 20 can be transferred to a right position.

Further, because it is not necessary to use a large linear guide unlike a conventional technology, it is possible to provide a transfer device 1 that particularly avoids increasing the size of a drive motor 9 for rotation and the production cost.

Furthermore, since a transfer device according to the present embodiment includes only rotary elements (configured so as to be pivotally supported with bearings), when it is necessary to use a dry lubricant (a solid lubricant), it is possible to use a technologically established dry bearing and provide a transfer device 1 having a large load capacity and a long service life without the contamination of an object to be transferred 20 and a vacuum environment.

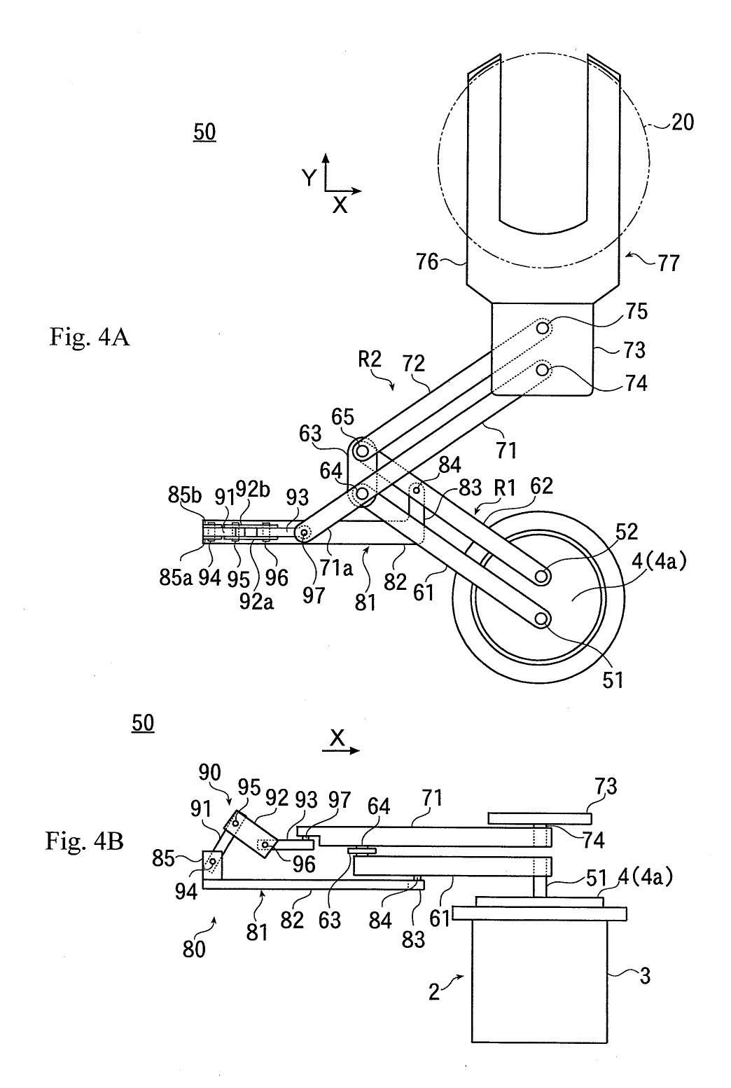

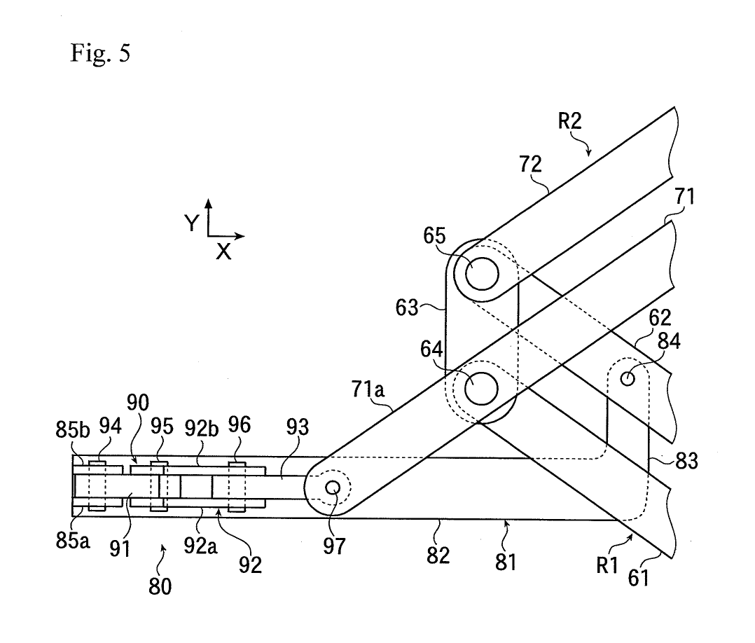

FIGS. 4A and 4B show a general configuration in another embodiment of a transfer device according to the present invention. FIG. 4A shows a plan view and FIG. 4B shows a front view of the transfer device. FIG. 5 is a plan view showing the main section of the transfer device.

Hereunder, a part corresponding to the part in the aforementioned embodiment is denoted by the same reference numeral and the detailed explanation is omitted.

As shown in FIGS. 4A and 4B, a transfer device 50 according to the present embodiment has a cylindrical casing 3 functioning as a device main body 2 similar to the above embodiment and a swivel 4 is contained in the casing 3.

The swivel 4 has a cylindrical shape and is attached to the inner wall of the casing 3 through a bearing (not shown) in the manner of being rotatable (swingable).

A drive motor (not shown) is provided inside the swivel 4, and a tip of a rotary shaft 51 of the drive motor protrudes from the upper face 4a of the swivel 4 in the vertical direction.

In the case of the present embodiment, the drive shaft 51 of the drive motor is positioned at a prescribed distance away backward from the rotation center of the swivel 4 in the substrate transfer direction (the direction indicated by the arrow Y in the figures).

An end of a linear first lower arm 61 having a prescribed length is fixed to the tip of the drive shaft 51, and thereby the first lower arm 61 rotates in the horizontal direction.

Further, a driven shaft 52 rotatable in the horizontal direction is provided on the upper face 4a of the swivel 4 in the manner of protruding in the vertical direction.

In the case of the present embodiment, the driven shaft 52 is positioned at a predetermined distance frontward from the aforementioned drive shaft 51 in the substrate transferring direction (the direction indicated by the arrow Y in the figure). In the present embodiment, the drive shaft 51 and the driven shaft 52 are aligned on a straight line passing through the center (diameter) of the swivel 4.

An end of a linear second lower arm 62 having the same distance between fulcrums as the first lower arm 61, for example, is fixed to a tip of the driven shaft 52, and thereby the second lower arm 62 is rotatable in the horizontal direction.

In addition, the other end of the first lower arm 61 and the other end of the second lower arm 62 are connected to a junction link member 63 having tabular shape, for example.

As shown in FIG. 4B, in the present embodiment, a first spindle 64 and a second spindle 65 are disposed so as to pierce through the junction link member 63, the other end of the first lower arm 61 is pivotally supported with the lower portion of the first spindle 64 in the manner of being rotatable, and the other end of the second lower arm 62 is pivotally supported with the lower portion of the second spindle 65 in the manner of being rotatable.

In addition, a first (drive-side) parallelogram link mechanism R1 is configured the first and second lower arms 61 and 62, the first and second spindles 64 and 65 of the junction link member 63, and the drive shaft 51 and the driven shaft 52 of the swivel 4.

Furthermore, a linear first upper arm 71 having a longer distance between fulcrums than the first and second lower arms 61 and 62 is pivotally supported with the upper portion of the first spindle 64 of the junction link member 63 at a middle portion of the first upper arm 71 in the manner of being rotatable in the horizontal direction.

An end of the first upper arm 71 is pivotally supported with a moving member 73 having a tabular shape, for example, in the manner of being rotatable.

A transfer section 77 formed by attaching a transfer table 76 to support an object to be transferred 20 is attached to the portion of the moving member 73 frontward in the substrate transfer direction and, in the present embodiment, the end of the first upper arm 71 is pivotally supported in the manner of being rotatable in horizontal direction around a spindle 74 disposed on the bottom face of the moving member 73. The distance between the spindle 64 and the spindle 74 of the first upper arm 71 (distance between fulcrums) is set so as to be the same as the distance between the fulcrums of the aforementioned first and second lower arms 61 and 62.

In addition, the other end (the tip of an extended portion 71a) of the first upper arm 71 is connected to a guide mechanism 80 that will be described later.

Meanwhile, an end of the linear second upper arm 72 is pivotally supported with the upper end of the second spindle 65 of the junction link member 63 in the manner of being rotatable in the horizontal direction. In the case of the present embodiment, the second upper arm 72 has the same distance between fulcrums as the aforementioned first and second lower arms 61 and 62.

Further, the other end of the second upper arm 72 is pivotally supported in the manner of being rotatable around a spindle 75 disposed on the bottom face of the moving member 73 in the horizontal direction.

In addition, a second (driven-side) parallelogram link mechanism R2 is configured with the first and second upper arms 71 and 72, the junction link member 63, and the spindles 74 and 75 of the moving member 73.

In the present embodiment, the first and second parallelogram link mechanisms R1 and R2 are configured so as to: have an identical configuration; be connected to each other through the junction link member 63 that is shared by them; and be operated.

Further, in the present embodiment, a guide mechanism 80 explained below may be installed.

The guide mechanism 80 according to the present embodiment comprises an L-shaped base member 81 and a guide link mechanism 90.

The base member 81 is integrally formed by combining a linear main body section 82 and a connector section 83 extending in a direction perpendicular to the main body section 82.

An end of the connector section 83 of the base member 81 is pivotally supported with a spindle 84 disposed on the bottom face of the second lower arm 62 in the manner of being rotatable in the horizontal direction.

An end of the main body section 82 of the base member 81 is connected to a guide link mechanism 90 having the following configuration.

The guide link mechanism 90 has a linear first guide arm 91, a linear second guide arm 92, and a linear third guide arm 93.

The first guide arm 91 is configured with a rod-shaped member and an end thereof is configured so as to rotate around a spindle 94 in the vertical direction in the state of being interposed between a pair of support members 85 (85a and 85b) disposed on the end upper face of the main body section 82 of the base member 81.

The second guide arm 92 is configured with a pair of identical members facing each other in the manner of interposing the other end of the first guide arm 91 and an end thereof is pivotally supported in the manner of being rotatable around a spindle 95 in the vertical direction.

Meanwhile, the third guide arm 93 is configured with a rod-shaped member, and an end thereof is configured so as to rotate around a spindle 96 in the vertical direction in the state of being interposed between the second guide arm 92.

Furthermore, the other end of the third guide arm 93 is pivotally supported in the manner of being rotatable in the horizontal direction around a spindle 97 disposed at the lower portion of the end of the extended portion 71a of the first upper arm 71.

Each of the three spindles 94, 95, and 96 of the guide link mechanism 90 is configured with a bearing. In addition, the shape and size of the L-shaped base member 81, the position of the spindle 84, and the length of the extended portion 71a of the first upper arm 71 are set so that the center axis of rotation of the spindles may always be identical to the moving direction of the moving member 73 (the direction indicated with the arrow Y or the opposite direction in the figures) and be horizontal.

By such a configuration, the range (direction) wherein the first to third guide arms 91, 92, and 93 of the guide link mechanism 90 are movable in the present embodiment is constrained only in the direction parallel to the X direction.

In the present embodiment further, the device is configured such that the direction of the rotation of the first parallelogram link mechanism R1 is opposite to the direction of the rotation of the second parallelogram link mechanism R2 and the angles formed with the Y direction are identical.

In the case of an embodiment having such a configuration, at expansion and contraction movement, when the drive shaft 51 is activated, the first lower arm 61 rotates around the drive shaft 51 in the horizontal direction, for example in a clockwise direction, resulting in the second lower arm 62 rotating around the driven shaft 52 in the horizontal direction, so that the first parallelogram link mechanism R1 moves in the horizontal direction while the junction link member 63 keeps the posture parallel to the Y direction.

In the present embodiment, because the range wherein the first to third guide arms 91, 92, and 93 of the guide 1 ink mechanism 90 are movable is constrained only in the direction parallel to the X direction and the second parallelogram link mechanism R2 rotates in the direction opposite to the direction of the first parallelogram link mechanism R1 so as to equalize the angles formed with the Y direction, the moving member 73 moves parallel in the Y direction (or the opposite direction) by activating the drive shaft 51.

In the present embodiment, the rotation movement is carried out by rotating the swivel 4 in the state that the moving member 73 is contracted.

In the present embodiment, in the same way as for the aforementioned embodiment, it is possible to provide a vacuum processing apparatus that has a small size and is hardly contaminated by grease, dust, and others.

Furthermore, in the present embodiment, because the guide link mechanism 90 of the guide mechanism 80 is configured with a plurality of guide arms 91 to 93 in particular, it is possible to apply corrosion protection easily by an existing technology.

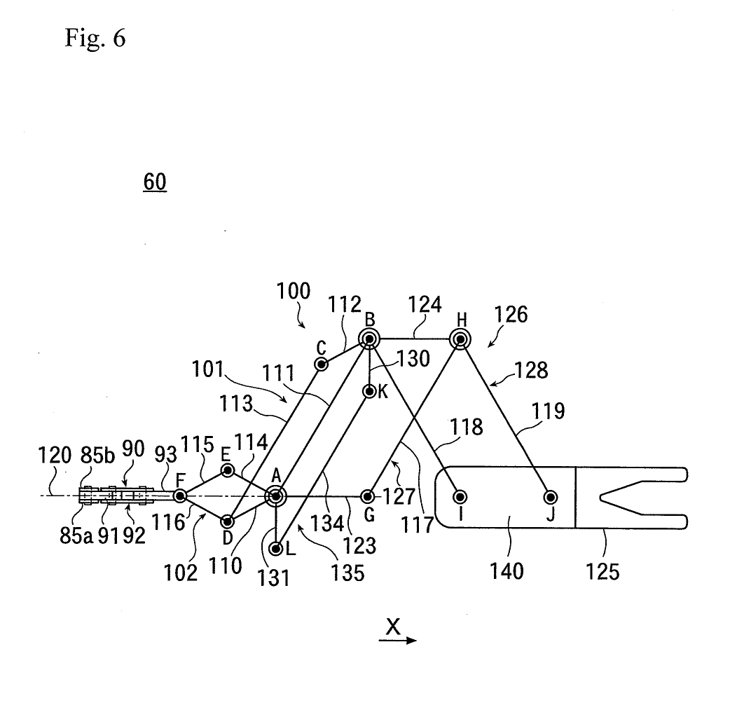

FIG. 6 is a plan view showing a general configuration in another embodiment of a transfer device according to the present invention. Parts corresponding to the parts described in the aforementioned embodiments are denoted by the same reference numerals as in FIG. 6, and their detailed explanations are omitted.

As shown in FIG. 6, a transfer device 60 according to the present embodiment is configured by combining the aforementioned guide link mechanism 90 with a transfer mechanism 100 that is explained below.

Firstly, the transfer mechanism 100 has a first parallelogram linkage 101 and a second parallelogram linkage 102.

The first parallelogram linkage 101 has fulcrums A to D and is configured with a link 110, a link 111, a link 112, and a link 113. As the links 111 and 113, members longer than the links 110 and 112 are used.

On the other hand, the second parallelogram linkage 102 shares the link 110 between the fulcrums A and D with the first parallelogram linkage 101 and is configured with the link 110 and a link 114, a link 115, and a link 116, the lengths of which are identical.

The link 110 shared by the first parallelogram linkage 101 and the second parallelogram linkage 102 is attached in the manner of being rotatable in the horizontal direction at both the edges thereof around the fulcrums A and D. The link 112 facing the link 110 in the first parallelogram linkage is attached in the manner of being rotatable in the horizontal direction at both the edges thereof around the fulcrums B and C.

The link 111 constituting the first parallelogram linkage and the link 114 constituting the second parallelogram linkage are configured so as to rotate around the fulcrum A at an end of the link 110 shared by the first and second parallelogram linkages 101 and 102 in the state of being constrained at an angle of 90 degrees, for example.

That is, an L-shaped link is formed by fastening the links 111 and 114, and the fastened portion is attached in the manner of being rotatable around the fulcrum A in the horizontal direction.

In addition, the device is configured such that a rotation drive force may be loaded on the L-shaped link consisting of the links 111 and 114 in the horizontal direction at the fulcrum A, for example.

Furthermore, the link 113 constituting the first parallelogram linkage and the link 116 constituting the second parallelogram linkage are configured so as to rotate around the fulcrum D at the other end of the link 110 shared by the first and second parallelogram linkages 101 and 102 in the state of being constrained at an angle of 90 degrees, for example.

That is, an L-shaped link is formed by fastening the link 113 constituting the first parallelogram linkage 101 and the link 116 constituting the second parallelogram linkage 102, and the fastened portion is attached in the manner of being rotatable around the fulcrum D in the horizontal direction.

Meanwhile, in the second parallelogram linkage 102, an end of the link 115 facing the aforementioned link 110 is attached in the manner of being rotatable around the fulcrum E located at the other end of the link 114 in the horizontal direction.

Further, an end of the link 116 constituting the aforementioned L-shaped link is attached to the other end of the aforementioned link 115 in the manner of being rotatable around the fulcrum F in the horizontal direction.

The fulcrum F is formed at a tip of the third guide arm 93 of the guide link mechanism 90 as it is explained below.

In the case of the present embodiment, the guide mechanism 90 has the first to third guide arms 91 to 93 configured so as to rotate in the vertical direction respectively, and is disposed on a transfer reference line 120 which passes through the above-discussed fulcrum A and is parallel to the X axis, and the aforementioned support member 85 (85a and 85b) is fixed to a base member (not shown).

Further, the aforementioned fulcrum A is provided on a base member identical to the guide link mechanism 90, and thereby the device is configured so as not to change the relative positional relationship of the guide link mechanism 90 to the fulcrum A.

By such a configuration, the guide link mechanism 90 and the second parallelogram linkage 102 expand and contract, and the fulcrum F at a tip of the third guide arm 93 moves on the transferring reference line 120 in the X direction or in the opposite direction.

Further, a parallel link type link mechanism 126 that is described below is connected to the aforementioned first and second parallelogram linkages 101 and 102.

The parallel link type link mechanism 126 has an upper arm linkage 127 and a lower arm linkage 128.

The upper arm linkage 127 shares the link 111 of the aforementioned first parallelogram linkage 101 and comprises the links 111 and 117, and the links 123 and 124, which face each other and are parallel to each other, respectively. Meanwhile, the lower arm linkage 128 is configured with links 118 and 119 and the link 124 and a transfer table 140 (fulcrums I and J), which face each other and are parallel to each other, respectively.

The links 123 and 124 are attached in the manner of being rotatable in the horizontal direction around the fulcrums A and B, respectively, at both the ends of the aforementioned link 111, and further the link 117 is attached in the manner of being rotatable in the horizontal direction around the fulcrums G and H, respectively, at the ends of the links 123 and 124 on the opposite side from the fulcrums A and B.

The fulcrum G is disposed on the aforementioned transfer reference line 120. Further, the fulcrum G is disposed on the same base member (not shown in the figure) as the fulcrum A, for example, and is configured so as not to change the relative positional relationship to the fulcrum A.

Meanwhile, the link 118 of the lower arm linkage 128 constitutes an L-shaped link by being fastened to the aforementioned link 112 at an angle of 90 degrees for example and the fastened portion is attached in the manner of being rotatable around the fulcrum B in the horizontal direction.

The link 119 facing the link 118 is attached in the manner of being rotatable around the fulcrum H of the upper arm linkage 127 in the horizontal direction and the tips of the links 118 and 119 are attached in the manner of being rotatable around the fulcrums I and J disposed on the transfer table 140 in the horizontal direction.

In the case of the present embodiment, the lengths of the links 123 and 124 (distances between fulcrums) and the distance between fulcrums (distance between fulcrums I and J) of the transfer table 140 are configured so as to be identical with each other, respectively. The lengths (distances between fulcrums) of the links 111 and 117, the links 118 and 119 are also configured so as to be identical with each other respectively. By this configuration, the fulcrums I and J on the transfer table 140 are located on the transfer reference line 120.

An end effector 125 to load an object to be transferred such as a wafer is attached to a tip of the transfer table 140.

In the present embodiment, a dead point passing mechanism 135, which is described below, to pass through a fixed point (dead point) is disposed.

A link 130 that is integrated with the link 112 and rotatable around the fulcrum B in the horizontal direction is attached to the connector section of the L-shaped arm consisting of the links 112 and 118, and further a link 131 that is integrated with the link 110 and rotatable around the fulcrum A in the horizontal direction is attached.

The mounting angle of the link 131 to the link 110 and the mounting angle of the link 130 to the link 112 are configured so as to be identical.

Further, a link 134 is attached in the manner of being rotatable in the horizontal direction around a fulcrum K at the end opposite to the fulcrum B of the link 130 and a fulcrum L at the end opposite to the fulcrum A of the link 131, respectively. The length of the link 134 is identical to the length of the link 111 (the distances between fulcrums are the same).

The links 111, 130, 134, and 131 constitute the dead point passing mechanism 135.

In the case of the present embodiment, it is desirable to decide the mounting angle of the link 131 to the link 110 and the mounting angle of the link 130 to the link 112 so as to be most appropriate from the viewpoint of the device configuration, the moving range, and other conditions. From the viewpoint of passing through the dead point stably, a preferable mounting angle is in the range of about 30 degrees to about 60 degrees.

In an embodiment having such a configuration, when the L-shaped links 111 and 114 rotate at an angle of θ around the fulcrum A in a clockwise direction, the link 114 rotates at an angle of θ around the fulcrum A in a clockwise direction together with the link 111.

In this case, the fulcrum F moves with the guide link mechanism 90 linearly toward the fulcrum A along the transfer reference line 120 in synchronization with the movement of the links 114 and 116.

By so doing, the second parallelogram linkage 102 changes the shape while keeping the shape of the parallelogram and the link 110 rotates at an angle of θ around the fulcrum A in a counterclockwise direction.

In the case of the present embodiment, because the links 110, 111, 112, and 113 constitute the first parallelogram linkage 101, when the link 110 rotates at an angle of θ around the fulcrum A in a counterclockwise direction, the link 112 rotates at an angle of θ around the fulcrum B in a counterclockwise direction, and thereby the link 118, together with the link 112, rotates at an angle of θ around the fulcrum B in a counterclockwise direction.

If it is viewed with reference to the fulcrum B, the series of movement means that, because the link 111 rotates at an angle of θ around the fulcrum B in a clockwise direction and simultaneously the link 118 rotates at an angle of θ around the fulcrum B in a counterclockwise direction, the link 118 rotates at an angle of 2θ with the link 111 around the fulcrum B in a counterclockwise direction.

Further, in the present embodiment, since links 111, 117, 123, and 124 constitute the parallelogram upper arm linkage 127, when the link 111 rotates at an angle of θ around the fulcrum A in a clockwise direction, the link 117 also rotates at an angle of θ around the fulcrum G in a clockwise direction, and thereby the link 124 moves while keeping the posture parallel to the link 123.

At the same time, as discussed above, the link 118 rotates at an angle of 2θ to the link 111 around the fulcrum B in a counterclockwise direction.

When the link 111 rotates at an angle of θ around the fulcrum A in a clockwise direction, the positions of the links 118 and 124 are fixed, the shape of the parallelogram of the lower arm linkage 128 is fixed unambiguously so that the transfer mechanism 100 carries out expansion movement.

As a result, the end effector 125 moves on the transferring reference line 120 in the X direction.

When the end effector 125 moves on the transfer reference line 120 in the direction opposite to the X direction, the link 111 rotates in the direction opposite to the direction of the aforementioned movement (in a counterclockwise direction).

By rotating the link 111 and thus carrying out the expansion and contraction movement of the transfer mechanism 100, it is possible to translate the transfer table 140 and the end effector 125 on the transfer reference line 120.

In the case of rotating the link 111 around the fulcrum A in a clockwise direction, although the link 110 rotates in a counterclockwise direction by the function of the guide link mechanism 90, the direction of the rotation of the link 112 cannot mandatorily be decided so that whether the link 112 rotates around the fulcrum B in a clockwise direction or in a counterclockwise direction is not determined.

In the case of the present embodiment, because the dead point passing mechanism 135 is installed and the link 131 is configured so as to be integrated with the movement of the link 110 and rotate around the fulcrum A in a counterclockwise direction, the link 130 rotates around the fulcrum B in a counterclockwise direction.

As a result, since the link 112 rotates around the fulcrum B in a counterclockwise direction in the manner of being integrated with the link 130, it is possible to escape from the dead point.

Likewise, when the links 111, 134, 130, and 131 constituting the dead point passing mechanism 135 are aligned on a straight line (on the dead point), the link 130 can escape from the dead point by the movement of the links 110 to 113 constituting the first parallelogram linkage 101.

As discussed above, in the present embodiment, the link 118 can stably rotate around the fulcrum B without the direction of rotation being indeterminate at the dead point.

As explained above, in the present embodiment, in the same way as the aforementioned embodiments, it is possible to provide a vacuum processing apparatus that has a small size and is hardly contaminated by grease, dust, and others.

In the present embodiment further, since the guide link mechanism 90 of the guide mechanism 80 is configured with a plurality of guide arms 91 to 93 in particular, it is possible to apply corrosion protection easily by an existing technology.

Furthermore, in the present embodiment, since the dead point passing mechanism 135 is configured so as to share the link 111 constituting the first parallelogram linkage 101, the link 118 rotates stably around the fulcrum B without being indeterminate the rotation at the dead point, and as a result, the lower arm linkage 128 can move stably beyond the fixed point position.

Other configuration and operational effects are identical to those in the aforementioned embodiments so that their detailed explanations are omitted.

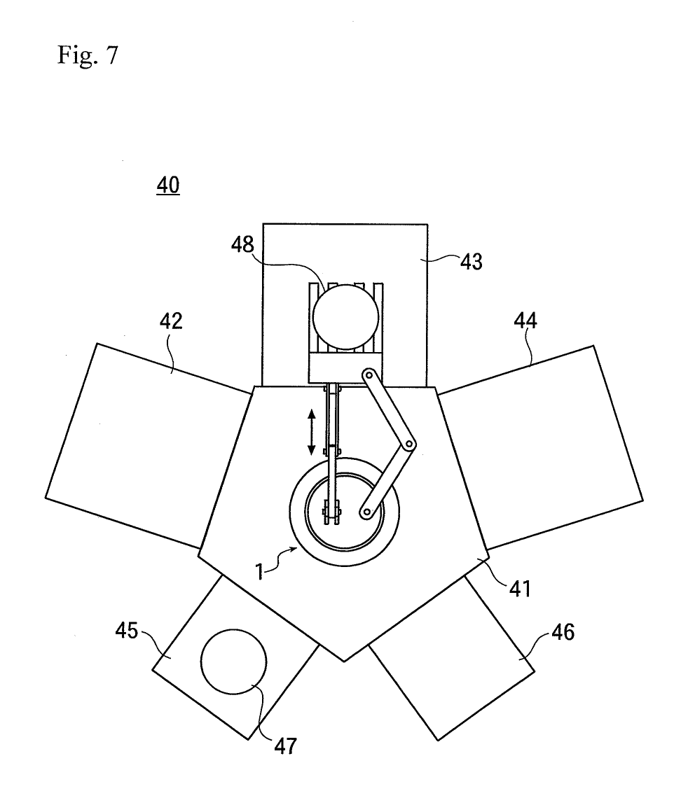

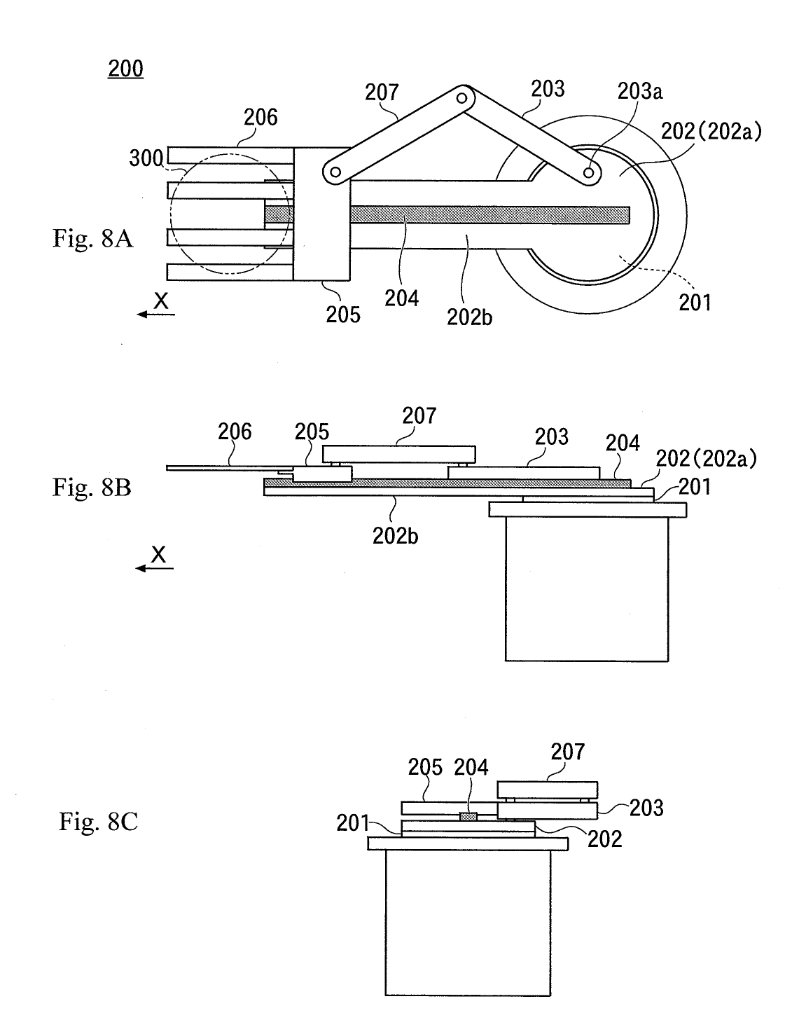

FIG. 7 is a plan view schematically showing a configuration in an embodiment of a vacuum processing apparatus having a transfer device according to the present invention.

As shown in FIG. 7, in a vacuum processing apparatus 40 according to the present embodiment, process chambers 42, 43, and 44 to carry out vacuum processing, such as, film forming in parallel, a carry-in chamber 45 to carry a wafer as an object to be transferred in, and a carry-out chamber 46 to carry a wafer out are installed around a transfer chamber 41 where an aforementioned transfer device 1 is installed through gate valves not shown in the figure.

The process chambers 42, 43, and 44, the carry-in chamber 45, and the carry-out chamber 46 are connected to an evacuation system (not shown).

In a vacuum processing apparatus 40 having such a configuration, an unprocessed wafer 47 contained in the carry-in chamber 45 is taken in with the transfer device 1 and is transferred to the process chamber 43, for example.

The transfer device 1 receives a processed wafer 48 from the process chamber 43 by, for example, performing the above operation and transfers the processed wafer 48 to another process chamber 42.

Successively, in the same way with the transfer device 1, an unprocessed wafer 47 and a processed wafer 48 are received and delivered between the process chambers 42 to 44, the carry-in chamber 45, and the carry-out chamber 46.

In the case of using another aforementioned transfer device 50 or 60 in place of the transfer device 1, the same operations are carried out.

In the present embodiment having such a configuration, it is possible to provide a vacuum processing apparatus that can smoothly transfer an object to be transferred and has a small size and a small base area. Further, it is possible to provide a vacuum processing apparatus that is hardly contaminated by dust, oil, and others.

The present invention can be variously modified without being limited to the aforementioned embodiments.

For example, although the guide mechanism includes arms pivotally supported in the manner of being rotatable in the vertical direction in the aforementioned embodiments, the present invention is not limited to such embodiments. The direction of the rotation of the arms is not limited to the vertical direction but it is also possible for the direction of the rotation of the arms to incline from the vertical direction.

Further, the number of the guide arms of the guide mechanism is not limited to two or three, and the guide mechanism may include more than three guide arms. In such a case, the shape of the guide arms is not limited to a linear shape.

In the meantime, although the power transmission mechanism consisting of link arms pivotally supported in the manner of being rotatable in the horizontal direction is used in the aforementioned embodiments, it is possible to incline the direction of the rotation of the arms and the like at an arbitrary angle to the horizontal direction.

1. A transfer device comprising:
a transfer section to support and transfer an object to be transferred;
a power transmission mechanism to transmit power from a device main body to the transfer section and move the transfer section toward a direction intersecting with a reference direction; and
a guide mechanism disposed between the device main body and the transfer section to guide the direction of movement of the transfer section,
wherein the guide mechanism has a plurality of pivotally connected guide arms and is configured such that each of the guide arms rotate toward a direction containing a component of the reference direction.

2. The transfer device according to claim 1, wherein the guide arms of the guide mechanism are configured such that a guide arm atone end of the guide mechanism is attached to the device main body and a guide arm at the other end thereof is attached to the transfer section.

3. The transfer device according to claim 1,
wherein the guide mechanism has a first guide arm and a second guide arm, and an end of the first guide arm is pivotally supported with the device main body so as to be rotatable in the vertical direction, and
wherein an end of the second guide arm is pivotally supported with the other end of the first guide arm in the manner of being rotatable in the vertical direction, and the other end of the second guide arm is pivotally supported with the transfer section in the manner of being rotatable in the vertical direction.

4. The transfer device according to claim 1,
wherein the power transmission mechanism has a drive arm and a driven arm,
an end of the drive arm is fixed to a drive shaft of the device main body in the manner of being rotatable in the horizontal direction,
the end of the driven arm is pivotally supported with an other end of the drive arm in the manner of being rotatable in the horizontal direction, and
the other end of the driven arm is pivotally supported with the transfer section so as to be rotatable in the horizontal direction.

5. The transfer device according to claim 4, wherein the power transmission mechanism includes a drive-side parallelogram link mechanism having the drive arm and a driven-side parallelogram link mechanism formed with a predetermined link in the drive-side parallelogram link mechanism.

6. The transfer device according to claim 5, wherein the guide mechanism is connected to the power transmission mechanism and configured so as to constrain the relative movement of the drive-side parallelogram link mechanism and the driven-side parallelogram link mechanism.

7. The transfer device according to claim 1, wherein an end of the power transmission mechanism on the side of the device main body is attached to a rotating section disposed on the device main body.

8. A vacuum processing apparatus comprising:
a transfer chamber containing the transfer device according to claim 1; and
a vacuum processing chamber communicating with the transfer chamber and being configured so as to receive and deliver an object to be processed using the transfer device.
